(19) United States
(12) Patent Application Publication
(10) Pub. No.: US 2011/0189862 A1
(43) Pub. Date: Aug. 4, 2011

(54) SILICON OXYNITRIDE FILM AND PROCESS FOR PRODUCTION THEREOF, COMPUTER-READABLE STORAGE MEDIUM, AND PLASMA CVD DEVICE

(75) Inventors: Minoru Honda, Hyogo (JP); Tatsuo Nishita, Hyogo (JP); Junya Miyahara, Hyogo (JP); Masayuki Kohno, Hyogo (JP)

(73) Assignee: TOKYO ELECTRON LIMITED, Tokyo (JP)

(21) Appl. No.: 13/121,610

(22) PCT Filed: Sep. 29, 2009
(86) PCT No.: PCT/JP2009/067306

§ 371 Date: Apr. 18, 2011

(30) Foreign Application Priority Data
Sep. 30, 2008 (JP) 2008-253933

(51) Int. Cl. H01L 21/314; C23C 16/48; H01B 1/08

(52) U.S. Cl. 438/786; 118/697; 118/696; 252/500; 257/E21.267

(57) ABSTRACT

Provided is a process of forming a silicon oxynitride film having concentration of hydrogen atoms below or equal to 9.9×10²⁰ atoms/cm³ as measured by using secondary ion mass spectrometry (SIMS), using a plasma CVD device, which generates plasma by introducing microwaves into a process chamber by using a planar antenna having a plurality of apertures, by setting a pressure inside the process chamber within a range from 0.1 Pa to 6.7 Pa, and performing plasma CVD by using process gases including SiCl₄ gas, nitrogen gas, and oxygen gas.

### TECHNICAL FIELD

The present invention relates to a silicon oxynitride film and process for production thereof, a computer-readable storage medium used in the process, and a plasma CVD device.

### BACKGROUND ART

Currently, a thermal oxidation method, a plasma oxidation method, a plasma nitrification method, etc. that perform an oxidation process or a nitrification process on silicon are used in combinations as methods of forming a high quality silicon dioxide film (SiO₂ film), silicon nitride film (SiN film), or silicon oxynitride film (SiON film) having high insulating properties. However, when a multilayer insulation film is formed, an oxidation process or a nitrification process cannot be used, and the multilayer insulation film may be formed by depositing a SiO₂ film or a SiN film by using a CVD (Chemical Vapor Deposition) method. In order to form a SiO₂ film or a SiN film having high insulating properties by using a CVD method, formation of the SiO₂ film or the SiN film needs to be performed at a high temperature from 600° C. to 900° C. Thus, a device may be adversely affected due to increase of a thermal budget, and moreover, several restrictions may be generated while preparing the device.

Meanwhile, a film may be formed at a temperature around 500° C. in a conventional plasma CVD method, but a charging damage may be generated due to plasma having a high electron temperature. Furthermore, although silane (SiH₄) or disilane (Si₂H₆) is generally used as a raw material for film formation in a plasma CVD method, a large amount of hydrogen originated from the raw materials is included in an insulation film formed by using the raw materials. A relationship between hydrogen existing in an insulation film and, for example, negative bias temperature instability (NBTI), which indicates shifting of a threshold value when a P-channel MOSFET is turned on, has been pointed out. As described above, since hydrogen in an insulation film may deteriorate reliability of the insulation film and adversely affect a device, it is thought that reduction of hydrogen in an insulation film as much as possible is preferable.

As a technique for forming an insulation film containing no hydrogen, patent reference 1 suggests a method of forming a silicon-based insulation film by depositing a silicon-based insulation film containing no hydrogen on a substrate using a hot-wall CVD method by introducing tetraisocyanatesilane, which is a silicon-based raw material containing no hydrogen, and an amine type 3 gas into a reaction container and reacting them to each other.

Furthermore, patent reference 2 also suggests a method of forming an oxynitride film substantially containing no hydrogen-related bond groups, such as H groups, —OH groups, or the like, or hydrogen-related bonds, such as Si—H bonds, Si—OH bonds, N—H bonds, or the like, therein by introducing a SiCl₄ gas, a N₂O gas, and a NO gas into a depressurized CVD device and performing depressurized CVD at a film formation temperature of 850° C. under a pressure of 2×10² Pa.

Furthermore, patent reference 3 suggests a method of manufacturing a semiconductor device including a process of forming a SiN film or a SiON film by using high density plasma CVD using an inorganic Si-based gas containing no H and N₂, NO, N₂O, or the like.

Although the method disclosed in the patent reference 1 enables a process at a low temperature around 200° C., the method is not a film formation technique using plasma. Furthermore, the method disclosed in the patent reference 2 is also not a film formation technique using plasma, and moreover, requires a relatively high film formation temperature of 850° C., and thus the method disclosed in the patent reference 2 may increase thermal budget and accordingly is not a satisfactory one.

Furthermore, a SiCl₄ gas used in the patent reference 1 and the patent reference 2 is dissociated in plasma with a high electron temperature and forms an active species (etchant) having an etching effect, thus causing deterioration of film formation efficiency. In other words, a SiCl₄ gas has been inappropriate as a raw material for film formation in plasma CVD. Although the patent reference 3 states that a SiCl₄ gas may be used as “an inorganic Si-based gas containing no H,” a gas used for forming a SiN film in a corresponding embodiment is a SiF₄ gas, and no actual verification has been made with respect to formation of a film using a SiCl₄ gas as a raw material by using plasma CVD, and thus the statement is nothing more than an assumption. Furthermore, since the patent reference 3 provides no detailed disclosure regarding high density plasma, no resolution with respect to formation of etchants when the SiCl₄ gas is used is provided.

Therefore, a technique for forming a fine quality SiON film having high insulation properties by using a plasma CVD method has not yet been established.

### PRIOR ART REFERENCE

### Patent Reference

(Patent Reference 1) Japanese Laid-Open Patent Publication No. hei 10-189582 (e.g., claim 1, or the like)
(Patent Reference 2) Japanese Laid-Open Patent Publication No. 2000-91337 (e.g., Paragraph 0033, or the like)
(Patent Reference 3) Japanese Laid-Open Patent Publication No. 2000-77406 (e.g., claim 1, claim 2, or the like)

### DISCLOSURE OF THE INVENTION

### Technical Problem

To solve the above problems, the present invention provides a process for production of a high quality silicon oxynitride film containing an extremely small amount of hydrogen therein and having high insulation property by using a plasma CVD method.

### Technical Solution

According to an aspect of the present invention, there is provided a process for production of a silicon oxynitride film on an object to be processed by using a plasma CVD method in a plasma CVD device that forms a film by generating plasma by introducing microwaves into a process chamber by using a planar antenna having a plurality of apertures, the process including forming a silicon oxynitride film having concentration of hydrogen atoms below or equal to 9.9×10²⁰ atoms/cm³ therein as measured by using secondary ion mass spectrometry (SIMS), by setting a pressure inside the process chamber in a range from 0.1 Pa to 6.7 Pa and performing plasma CVD by using process gases including a gas of a compound composed of silicon atoms and chlorine atoms, a nitrogen gas, and an oxygen gas.

No peak of N—H bonds may be detected from the silicon oxynitride film by using Fourier transform infrared spectroscopy (FT-IR).

The compound composed of silicon atoms and chlorine atoms may be tetrachlorosilane (SiCl₄).

A flow rate ratio of the gas of the compound composed of silicon atoms and chlorine atoms to the entire process gases may be in a range from 0.06% to 2%.

A flow rate ratio of the nitrogen gas to entire process gases is in a range from 32% to 99.8%.

A flow rate ratio of the oxygen gas to entire process gases may be in a range from 0.1% to 10%

According to another aspect of the present invention, there is provided a silicon oxynitride film produced by using the process of any one of claims 1 through 6.

According to another aspect of the present invention, there is provided a computer-readable storage medium having recorded thereon a control program to be operated on a computer, wherein the control program enables the computer to control a plasma CVD device that generates plasma by introducing microwaves into a process chamber by using a planar antenna having a plurality of apertures and performs film formation so as to form a silicon oxynitride film having concentration of hydrogen atoms below or equal to 9.9×10²⁰ atoms/cm³ in the silicon oxynitride film, as measured by using secondary ion mass spectrometry (SIMS) by setting a pressure inside the process chamber in a range from 0.1 Pa to 6.7 Pa and performing plasma CVD by using process gases including a gas of a compound composed of silicon atoms and chlorine atoms, a nitrogen gas, and an oxygen gas.

According to another aspect of the present invention, there is provided a plasma CVD device for production of a silicon oxynitride film on an object to be processed by using a plasma CVD method, the plasma CVD device including a process chamber which accommodates the object to be processed and has an opening on a top of the process chamber; a dielectric member which closes the opening of the process chamber; a planar antenna which is installed on the dielectric member and has a plurality of apertures for introducing microwaves into the process chamber; a gas introduction unit which is connected to a gas supply apparatus for supplying process gases into the process chamber; an exhauster which depressurizes and exhausts an inside of the process chamber; and a control unit which controls plasma CVD to be performed to set a pressure inside the process chamber to be in the range from 0.1 Pa to 6.7 Pa and to produce the silicon oxynitride film having concentration of hydrogen atoms below or equal to 9.9×10²⁰ atoms/cm³ in the silicon oxynitride film, as measured by using secondary ion mass spectrometry (SIMS) by supplying the process gases including a gas of a compound composed of silicon atoms and chlorine atoms, nitrogen gas, and oxygen gas from the gas introduction unit connected to the gas supply apparatus.

### Advantageous Effects

According to a method for forming a silicon oxynitride film of the present invention, a high quality silicon oxynitride film having extremely small amount of hydrogen and high insulating properties can be formed using a plasma CVD method, by using a gas of a compound composed of silicon atoms and chlorine atoms, and nitrogen gas, and oxygen gas as raw materials for film formation.

Since a silicon oxynitride film obtained by the method of the present invention causes no adverse effects to a device due to hydrogen, and has excellent insulating properties, the silicon oxynitride film can provide high reliability to a device. Accordingly, the process of the present invention has a high utility value in preparing a silicon oxynitride film that is used as a gate insulation film or the like.

### BRIEF DESCRIPTION OF THE DRAWINGS

FIG. 1 is a schematic cross-sectional view showing an example of a plasma CVD device suitable for forming a silicon oxynitride film;

FIG. 2 is a diagram of a structure of a planar antenna;

FIG. 3 is a diagram for explaining a structure of a control unit;

FIGS. 4A and 4B are diagrams showing an example of processes of a method for forming a silicon oxynitride film, according to the present invention;

FIG. 5 is a graph showing results of measuring concentrations of Si, N, and O in a silicon oxynitride film by using XPS;

FIG. 6 is a graph showing results of measuring a gate leak current of a MOS transistor prepared by using a silicon oxynitride film; and

FIG. 7 is a view for explaining a schematic structure of a MOS type semiconductor memory device to which a method of the present invention is applicable.

### BEST MODE FOR CARRYING OUT THE INVENTION

### First Embodiment

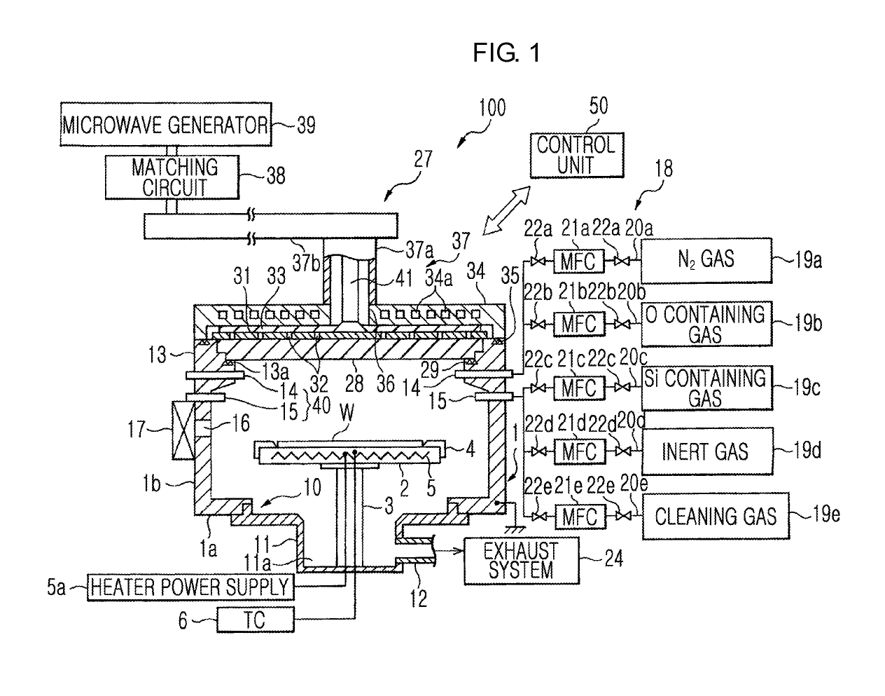

Hereinafter, the present invention will be described in detail by explaining exemplary embodiments of the invention with reference to the attached drawings. FIG. 1 is a schematic cross-sectional view showing a schematic structure of a plasma CVD device 100 used in a process for production of a silicon oxynitride film according to the present invention.

The plasma CVD device 100 is configured as a RLSA (Radial Line Slot Antenna) microwave plasma process apparatus that can generate microwave excitation plasma having a high density and a low electron temperature, by generating plasma by introducing microwaves into a process chamber by using a planar antenna including a plurality of apertures each having a slot shape, specifically a RLSA. The plasma CVD device 100 is able to perform a process using plasma having a low electron temperature from 0.7 eV to 2 eV, and a plasma density from 1×10¹⁰/cm³ to 5×10¹²/cm³. Accordingly, the plasma CVD device 100 may be very suitably used to form a silicon oxynitride film by using plasma CVD while manufacturing various semiconductor devices.

Important elements of the plasma CVD device 100 include an airtight process chamber 1, gas introduction units 14 and 15 connected via a gas introduction pipe to a gas supply apparatus 18 for supplying a gas into the process chamber 1, an exhauster 24 constituting an exhaust apparatus for depressurizing and exhausting an inside of the process chamber 1, a microwave introduction apparatus 27 disposed above the process chamber 1 and for introducing microwaves into the process chamber 1, and a control unit 50 for controlling each element of the plasma CVD device 100. Also, in the embodiment of FIG. 1, the gas supply apparatus 18 is integrally installed to the plasma CVD device 100, but may not be integrally installed. The gas supply apparatus 18 may be installed outside the plasma CVD device 100.

The process chamber 1 is a grounded container having an approximately cylindrical shape. Alternatively, the process chamber 1 may be a container having a prismatic shape. The process chamber 1 has a bottom wall 1a and a side wall 1b that are formed of a material such as aluminum or the like.

A holding stage 2 for horizontally supporting a silicon wafer (hereinafter, simply referred to as a “wafer”) W constituting an object to be processed is installed inside the process chamber 1. The holding stage 2 is formed of a material having a high thermal conductivity, for example, a ceramic, such as AlN or the like. The holding stage 2 is supported by a supporting member 3 having a cylindrical shape extending upward from a bottom center of an exhaust chamber 11. The supporting member 3 may be formed of a ceramic, such as AlN or the like.

A cover ring 4 for covering an outer edge portion of the holding stage 2 and guiding the wafer W is installed on the holding stage 2. The cover ring 4 is a ring-shaped member formed of a material such as quartz, AlN, Al₂O₃, SiN, or the like.

A resistance heating type heater 5 is embedded in the holding stage 2, to serve as a temperature adjusting apparatus. The heater 5 heats the holding stage 2 by receiving power from a heater power supply 5a, and the wafer W constituting a substrate to be processed is uniformly heated by heat from the holding stage 2.

A thermocouple (TC) 6 is disposed at the holding stage 2. A temperature is measured by using the thermocouple 6, and thus a heating temperature of the wafer W is controllable, for example, in the range from room temperature to 900° C.

Also, the holding stage 2 includes wafer support pins (not shown) for supporting and elevating the wafer W. Each wafer support pin is installed to be able to protrude and retract with respect to a surface of the holding stage 2.

A circular opening 10 is formed around a center of the bottom wall 1a of the process chamber 1. The exhaust chamber 11, which protrudes downward from the bottom wall 1a and communicates with the opening 10, is continuously installed on the bottom wall 1a. The exhaust chamber 11 is connected to an exhaust pipe 12, and is connected to the exhauster 24 through the exhaust pipe 12.

A plate 13 formed of a metal and functioning as a lid for opening and closing the process chamber 1 is disposed on an upper end of the side wall 1b forming the process chamber 1. An opening is formed in the plate 13, and a bottom inner circumference of the plate 13 protrudes inward (toward a space inside the process chamber 1) to form a ring-shaped supporter 13a.

A gas introduction unit 40 is disposed at the plate 13, and the gas introduction unit 14 having a ring shape and a first gas introduction hole is installed to the gas introduction unit 40. Also, the gas introduction unit 15 having a ring shape and a second gas introduction hole is installed on the side wall 1b of the process chamber 1. In other words, the gas introduction units 14 and 15 are installed in 2 stages consisting of a top stage and a bottom stage. Each of the gas introduction units 14 and 15 is connected to the gas supply apparatus 18 for supplying process gases or a gas for plasma excitation. Alternatively, the gas introduction units 14 and 15 may each have a nozzle shape or a shower head shape. Alternatively, the gas introduction units 14 and 15 may be installed as a single shower head.

A transfer hole 16 for transferring the wafer W between the plasma CVD device 100 and a transfer chamber (not shown) adjacent to the plasma CVD device 100, and a gate valve 17 for opening and closing the transfer hole 16 are installed on the side wall 1b of the process chamber 1.

The gas supply apparatus 18 includes, for example, a nitrogen gas (N₂) supply source 19a, an oxygen containing gas (O-containing gas) supply source 19b, a silicon containing gas (Si-containing gas) supply source 19c, an inert gas supply source 19d, and a cleaning gas supply source 19e. The nitrogen gas (N₂) supply source 19 and the oxygen containing gas supply source 19b are connected to the gas introduction unit 14 as the top stage of the two stages. Also, the silicon containing gas supply source 19c, the inert gas supply source 19d, and the cleaning gas supply source 19e are connected to the gas introduction unit 15 as the bottom stage of the two stages. The cleaning gas supply source 19e is used to clean unnecessary films adhered inside the process chamber 1. Also, the gas supply apparatus 18 may include, for example, a purge gas supply source or the like used to replace an atmosphere inside the process chamber 1, as another gas supply source (not shown).

In the present invention, a nitrogen gas (N₂) is used. Since the nitrogen gas (N₂) gas does not contain hydrogen in molecules, the nitrogen gas (N₂) may be preferably used in the present invention. Also, as a Si-containing gas, a gas of a compound (SiₙCl₂ₙ₊₂) composed of Si atoms and Cl atoms, e.g., tetrachlorosilane (SiCl₄), hexachlorosilane (Si₂Cl₆), or the like, is used. Here, since SiCl₄, Si₂Cl₆, and Si₃Cl₈ do not contain hydrogen in molecules, SiCl₄, Si₂Cl₆, and Si₃Cl₈ may be preferably used in the present invention. Also, for example, O₂, NO, N₂O, or the like may be used as the oxygen containing gas. Also, for example, a rare gas may be used as the inert gas. The rare gas helps generation of stable plasma, as a plasma excitation gas, and for example, an Ar gas, a Kr gas, a Xe gas, a He gas, or the like may be used as the rare gas. Alternatively, the rare gas may be used as a carrier gas for supplying the Si-containing gas, such as SiCl₄ or the like.

The nitrogen gas (N₂) and the oxygen containing gas reach the gas introduction unit 14 respectively from the nitrogen gas (N₂) supply source 19a and the oxygen containing gas supply source 19b of the gas supply apparatus 18 respectively through gas lines 20a and 20b, and are introduced into the process chamber 1 from a gas introduction hole (not shown). Meanwhile, the silicon containing gas, the inert gas, and the cleaning gas reach the gas introduction unit 15 respectively from the Si-containing gas supply source 19c, the inert gas supply source 19d, and the cleaning gas supply source 19e respectively through the gas lines 20c through 20e, and are introduced into the process chamber 1 from a gas introduction hole (not shown) of the gas introduction unit 15. Mass flow controllers 21a through 21e and opening and closing valves 22a through 22e respectively in front and behind the mass flow controllers 21a through 21e are respectively installed in the gas lines 20a through 20e respectively connected to the gas supply sources. A switch of supplied gases, a flow rate, and the like are controllable by such a structure of the gas supply apparatus 18. Here, the rare gas for plasma excitation, such as Ar or the like, is a predetermined gas, and does not have to be supplied at the same time as with process gases, but may be added in order to stabilize plasma.

The exhauster 24 constituting an exhaust apparatus includes a high speed vacuum pump, such as a turbomolecular pump or the like. As described above, the exhauster 24 is connected to the exhaust chamber 11 of the process chamber 1 through the exhaust pipe 12. By operating the exhauster 24, a gas inside the process chamber 1 uniformly flows inside a space 11a of the exhaust chamber 11, and is also exhausted from the space 11a to an exterior through the exhaust pipe 12. Accordingly, it is possible to depressurize the inside of the process chamber 1, for example, up to 0.133 Pa, at a high speed.

A structure of the microwave introduction apparatus 27 will now be described. Important elements of the microwave introduction apparatus 27 include a penetration plate 28, a planar antenna 31, a wavelength-shortening material 33, a conductive cover member 34, a waveguide 37, and a microwave generator 39.

The penetration plate 28 through which microwaves penetrate is arranged on the supporter 13a protruding in a long manner toward an inner circumference of the plate 13. The penetration plate 28 is formed of a dielectric material, for example, a ceramic such as quartz, Al₂O₃, AlN, or the like. A space between the penetration plate 28 and the supporter 13a is sealed air tight by disposing a seal member 29. Accordingly, the process chamber 1 is held air tight.

The planar antenna 31 is installed above the penetration plate 28 to face the holding stage 2. The planar antenna 31 has a disk shape. However, a shape of the planar antenna 31 is not limited to the disk shape, and, for example, the planar antenna 31 may have a rectangular plate shape. The planar antenna 31 is engaged with a top end of the plate 13.

The planar antenna 31 is formed of, for example, a plate such as a copper plate, a nickel plate, a SUS plate, or an aluminum plate, which has a surface coated with gold or silver. The planar antenna 31 includes a plurality of microwave radiation holes 32 each having a slot shape and for radiating microwaves. The microwave radiation holes 32 penetrate and are arranged through the planar antenna 31 in a predetermined pattern.

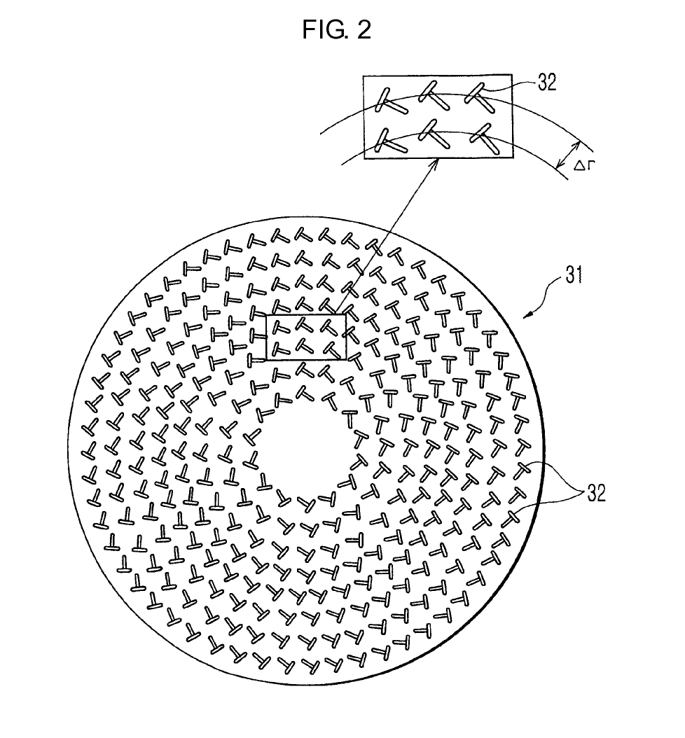

Each microwave radiation hole 32 has, for example, a thin and long rectangular shape (slot shape) as shown in FIG. 2, and two adjacent microwave radiation holes form a pair. The adjacent microwave radiation holes 32 are typically arranged in a “T”, “L”, or “V” shape, for example. Also, the microwave radiation holes 32 disposed after combining in such a predetermined shape (e.g., a “T” shape) are also arranged overall in a concentric shape.

Lengths or arranged intervals of the microwave radiation holes 32 are determined according to a wavelength (λg) of microwaves. For example, an interval of the microwave radiation holes 32 is arranged to be from to

$$\frac{λ g}{4}$$

λg. In FIG. 2, an interval between the adjacent microwave radiation holes 32 arranged in a concentric shape is Δr. Alternatively, a shape of microwave radiation hole 32 may vary and be, for example, a circular shape, an arc shape, or the like. Also, an arrangement of the microwave radiation holes 32 is not specifically limited, and may be, for example, a spiral shape, a radial shape or the like aside from the concentric shape.

The wavelength-shortening material 33, having a dielectric constant higher than vacuum, is installed on a top surface of the planar antenna 31. The wavelength-shortening material 33 shortens a wavelength of microwaves in order to adjust plasma, since the wavelength of the microwaves lengthens in a vacuum.

Also, the planar antenna 31 and the penetration plate 28, and the wavelength-shortening material 33 and the planar antenna 31 may contact or be separated from each other, but preferably contact each other.

The conductive cover member 34 may be formed on an upper portion of the process chamber 1 so as to cover the planar antenna 31 and the wavelength-shortening material 33. The conductive cover member 34 may be formed of, for example, a metal material such as aluminum, stainless steel, or the like. A top of the plate 13 and the conductive cover member 34 are sealed by a seal member 35. A cooling water path 34a may be formed inside the conductive cover member 34. Cooling water flows through the cooling water path 34a, thereby cooling the conductive cover member 34, the wavelength-shortening material 33, the planar antenna 31, and the penetration plate 28. Also, the conductive cover member 34 is grounded.

An opening 36 is formed on a center of a top wall (ceiling portion) of the conductive cover member 34, and the waveguide 37 is connected to the opening 36. Another end of the waveguide 37 is connected to the microwave generator 39 for generating microwaves, through a matching circuit 38.

The waveguide 37 includes a coaxial waveguide 37a having a circular cross-section and extending upward from the opening 36 of the conductive cover member 34, and a rectangular waveguide 37b connected to an upper end of the coaxial waveguide 37a and extending in a horizontal direction.

An inner conductor 41 extends in a center of the coaxial waveguide 37a. A bottom portion of the inner conductor 41 is connected and fixed to a center of the planar antenna 31. According to such a structure, microwaves are efficiently uniformly propagated in a radial shape to the planar antenna 31 through the inner conductor 41 of the coaxial waveguide 37a.

By using the microwave introduction apparatus 27 having the above structure, microwaves generated in the microwave generator 39 are propagated to the planar antenna 31 through the waveguide 37, and then are introduced into the process chamber 1 through the penetration plate 28. Also, a frequency of the microwaves may be, for example, 2.45 GHz, and may be 8.35 GHz, 1.98 GHz, or the like, aside from 2.45 GHz.

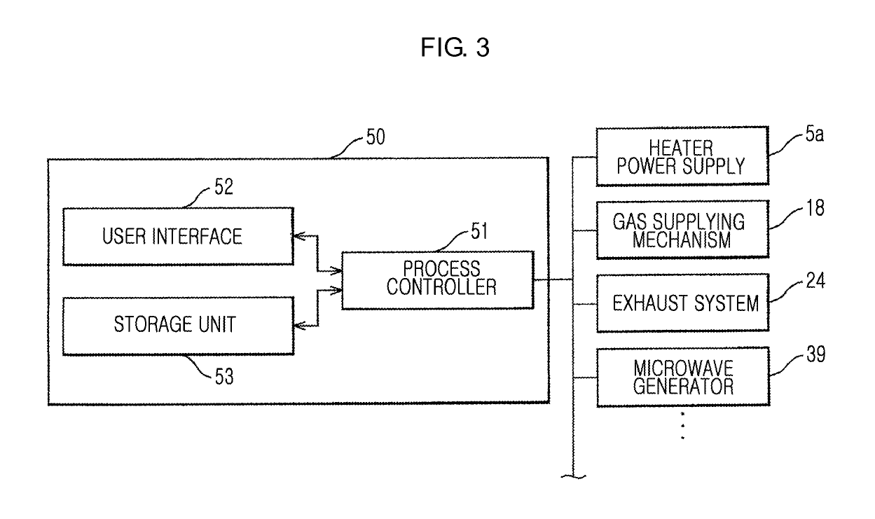

Each element of the plasma CVD device 100 is connected to and controlled by the control unit 50. The control unit 50 includes a computer, and, for example, includes a process controller 51 having a CPU, and a user interface 52 and a storage unit 53 connected to the process controller 51, as shown in FIG. 3. The process controller 51 is a control unit that generally controls elements of the plasma CVD device 100 that are related to, for example, process conditions, such as a temperature, a pressure, a gas flow rate, a microwave output, etc. (for example, the heater power supply 5a, the gas supply apparatus 18, the exhauster 24, the microwave generator 39, etc.).

The user interface 52 includes a keyboard for an operation manager to perform input manipulation or the like of a command to manage the plasma CVD device 100, a display for visually displaying an operation situation of the plasma CVD device 100, and the like. Also, the storage unit 53 stores a control program (software) for executing various processes in the plasma CVD device 100 under a control of the process controller 51, or a recipe on which process condition data, etc. is recorded.

Also, if required, a predetermined recipe is called from the storage unit 53 via instructions from the user interface 52 or the like and executed in the process controller 51, thereby performing a desired process in the process chamber 1 of the plasma CVD device 100 under a control of the process controller 51. The control program and the recipe recording process condition data or the like may be stored in a computer readable storage medium, such as a CD-ROM, a hard disk, a flexible disk, a flash memory, a DVD, a Blu-ray disk, or the like, and accessed therefrom. Alternatively, the control program, the recipe, such as the process condition data, or the like may be frequently received from another device, for example, through an exclusive line, and accessed online.

Next, a deposition process of a silicon oxynitride film by using a plasma CVD method using the RLSA type plasma CVD device 100 will be described. First, the gate valve 17 is opened and the wafer W is transferred to the process chamber 1 through the transfer hole 16 and placed on the holding stage 2. Then, while depressurizing and exhausting the inside of the process chamber 1, the nitrogen gas (N₂), the oxygen containing gas, the Si-containing gas, and, if required, the inert gas are introduced into the process chamber 1 respectively from the nitrogen gas (N₂) supply source 19a, the oxygen containing gas supply source 19b, the silicon containing gas supply source 19c, and the inert gas supply source 19d of the gas supply apparatus 18 respectively through the gas introduction units 14 and 15, at predetermined flow rates. Also, the inside of the process chamber 1 is set to a predetermined pressure. Conditions at this time will be described later.

Then, microwaves of a predetermined frequency, for example, 2.45 GHz, generated in the microwave generator 39 are led to the waveguide 37 through the matching circuit 38. The microwaves led to the waveguide 37 sequentially pass through the rectangular waveguide 37b and the coaxial waveguide 37a, and are supplied to the planar antenna 31 through the inner conductor 41. The microwaves are propagated in a radial shape from the coaxial waveguide 37a toward the planar antenna 31. Also, the microwaves are radiated to a space above the wafer W in the process chamber 1 from the microwave radiation holes 32 each having a slot shape of the planar antenna 31 through the penetration plate 28.

An electric field is formed inside the process chamber 1 by the microwaves radiated to the process chamber 1 from the planar antenna 31 through the penetration plate 28, and thus the nitrogen gas (N₂), a gas only containing Si and Cl such as SiCl₄ gas or the like, and the oxygen containing gas are each plasmatized. Then, a raw gas is efficiently dissociated in the plasma, and a thin film of silicon oxynitride (SiON) is deposited according to a reaction of active species of SiCl₃, SiCl₂, SiCl, Si, O, N, etc. Also, after forming the silicon oxynitride film on a substrate, a ClF₃ gas is supplied as a cleaning gas into the chamber and the chamber is cleaned by being heated from 100° C. to 500° C., preferably from 200° C. to 300° C., to remove silicon oxynitride films deposited unnecessarily in the chamber. Alternatively, when NF₃ is used as a cleaning gas, plasma is generated at a temperature from room temperature to 300° C. and the silicon oxynitride films deposited unnecessarily in the chamber are removed.

The above conditions are stored as a recipe in the storage unit 53 of the control unit 50. Also, the process controller 51 reads the recipe, and transmits a control signal to each element of the plasma CVD device 100, for example, the heater power supply 5a, the gas supply apparatus 18, the exhauster 24, the microwave generator 39, etc., thereby realizing a plasma CVD process performed under a desired condition.

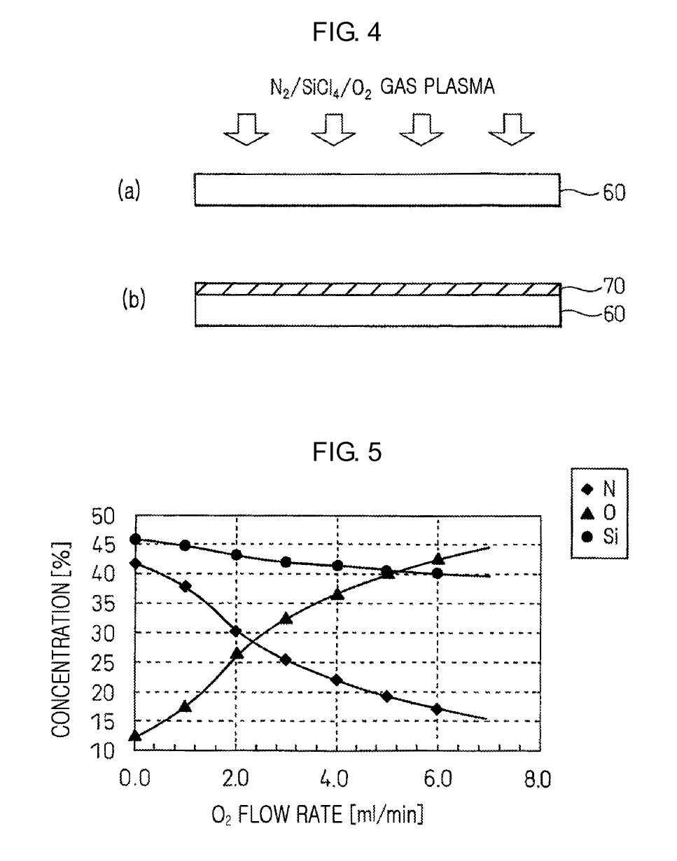

FIGS. 4A and 4B are process diagrams showing processes of forming a silicon oxynitride film performed by the plasma CVD device 100. As shown in FIG. 4A, a plasma CVD process is performed on a predetermined base layer (for example, a Si substrate) 60 by using the plasma CVD device 100. The plasma CVD process is performed under following conditions by using process gases including the SiCl₄ gas as the gas only containing Si and Cl, the nitrogen gas (N₂), and an O₂ gas as the oxygen containing gas.

A process pressure may be set in the range from 0.1 Pa to 6.7 Pa, and preferably in the range from 0.1 Pa to 4 Pa. The lower the process pressure the better, and the lowest limit 0.1 Pa of the range is set based on a restriction of a device (limitation of a high vacuum level). When the process pressure exceeds 6.7 Pa, a SiCl₄ gas does not dissociate, and thus a film may not be sufficiently formed.

Also, a ratio of a flow rate of the silicon containing gas to a flow rate of all gases (for example, a percentage of flow rate of SiCl₄ gas/flow rate of all gases) may be from 0.06% to 2%. Also, the flow rate of the silicon containing gas may be set to be from 0.5 mL/min (sccm) to 2 mL/min (sccm).

Also, a ratio of a flow rate of the nitrogen gas (N₂) to the flow rate of the all gases (for example, a percentage of flow rate of N₂ gas/flow rate of all gases) may be from 32% to 99.8%. The flow rate of the nitrogen gas (N₂) may be set to be from 100 mL/min (sccm) to 1000 mL/min (sccm), preferably from 300 mL/min (sccm) to 1000 mL/min (sccm), and more preferably from 300 mL/min (sccm) to 600 mL/min (sccm).

Also, a ratio of a flow rate of the oxygen containing gas to the flow rate of the all gases (for example, a percentage of flow rate of O₂ gas/flow rate of all gases) may be from 0.1% to 10%, and preferably from 0.2% to 5%. The flow rate of the oxygen containing gas may be set to be from 1 mL/min (sccm) to 10 mL/min (sccm), and preferably from 2 mL/min (sccm) to 10 mL/min (sccm).

Also, if the inert gas is added, the inert gas may be supplied with a flow rate smaller than or equal to that of the nitrogen gas. A ratio of a flow rate of the inert gas to the flow rate of all gases (for example, a percentage of flow rate of Ar gas/flow rate of all gases) may be from 0% to 66%. The flow rate of the inert gas may be set to be from 0 mL/min (sccm) to 200 mL/min (sccm).

Also, a temperature of the plasma CVD process may be set to be such that a temperature of the holding stage 2 is equal to or greater than 300° C., preferably in the range from 400° C. to 600° C., and more preferably from 400° C. to 550° C.

Also, a microwave output in the plasma CVD device 100 may be in the range from 0.25 W/cm² to 2.56 W/cm² as power density per area of the penetration plate 28. Preferably, a microwave output in the plasma CVD device 100 as power density per area of the penetration plate 28 may be in the range from 0.75 W/cm² to 2.56 W/cm². The microwave output may be selected to be a power density within the range, for example, from 500 W to 5000 W, and preferably from 1500 W to 5000 W, according to a purpose.

As shown in FIG. 4B, plasma of a N₂/SiCl₄/O₂ gas is formed via plasma CVD, and thus a silicon oxynitride film (SiON) 70 may be deposited. The plasma CVD device 100 is advantageous since a silicon oxynitride film having a film thickness in the range, for example, from 2 nm to 50 nm, preferably from 2 nm to 10 nm, is formed by using the plasma CVD device 100.

The silicon oxynitride film 70 obtained as described above has excellent insulating properties and contains no hydrogen atoms H originated from a raw material for film formation. In other words, the silicon oxynitride film 70 contains a very small amount of hydrogen. Therefore, adverse effects on a device due to hydrogen (e.g., NBTI) may be prevented, and thus reliability of the device may be improved. Accordingly, the silicon oxynitride film 70 formed by using the method of the present invention may preferably be used for a purpose that requires high reliability, for example, for a gate insulation film (tunnel insulation film), etc. of a semiconductor memory device.

### (Mechanism)

In the process for production of a silicon oxynitride film according to the present invention, a silicon oxynitride film containing a very small amount of hydrogen atoms H therein may be formed by using a nitrogen gas, a gas of a compound composed of Si atoms and Cl atoms (Si-containing gas), and an oxygen containing gas. It is thought that the SiCl₄ gas used in the present invention is dissociated in plasma according to following steps from i) to iv).

i) SiCl₄→SiCl₃+Cl

ii) SiCl₃→SiCl₂+Cl+Cl

iii) SiCl₂→SiCl+Cl+Cl+Cl

iv) SiCl→Si+Cl+Cl+Cl+Cl

(Here, Cl denotes ions)

In plasma having a high electron temperature, such as plasma used in a conventional plasma CVD method, the dissociation reaction shown in the i) to iv) may easily occur due to high energy of the plasma, and thus SiCl₄ molecules are easily separated and apt to become a high dissociated state. Thus, etching dominated as a large amount of etchant, such as Cl ions or the like constituting active species having an etching effect, was generated from the SiCl₄ molecules, and thus a silicon oxynitride film could not be deposited. Accordingly, until now, the SiCl₄ gas was not used as a film formation raw material of plasma CVD executed on an industrial scale.

The plasma CVD device 100 used in the method of the present invention was able to form plasma having a low electron temperature via a configuration of generating plasma by introducing microwaves into the process chamber 1 by using the planar antenna 31 having a plurality of slots (the microwave radiation holes 32). Thus, energy of plasma is low even if the SiCl₄ gas is used as a film formation raw material by controlling a process pressure and a flow rate of the process gases to be within the above ranges by using the plasma CVD device 100. Accordingly, dissociation is largely performed on SiCl₃ and SiCl₂, thereby maintaining a low dissociation state, and thus film formation dominates. In other words, dissociation of SiCl₄ molecules is suppressed in the steps of i) or ii) by plasma having a low electron temperature and low energy, thereby suppressing formation of the etchant (Cl ions or the like) that adversely affects film formation, and thus the film formation dominates.

Since the plasma of the method of the present invention has a low electron temperature and a high concentration of electron density, dissociation of the SiCl₄ gas is easy, and thus a lot of SiCl₃ ions are generated, and even a nitrogen gas (N₂) having high bonding energy is dissociated in high concentration plasma to become N ions. Also, it is thought that SiON is generated as SiCl₃ ions and N ions react with each other in an atmosphere containing activated oxygen. Accordingly, by using the nitrogen gas (N₂), it is possible to form a silicon oxynitride film. Accordingly, it is possible to form a high quality silicon oxynitride film having small film damage by ions and a very low hydrogen amount by using plasma CVD in which the SiCl₄ gas is used as a raw material.

Also, since the process gases are slowly dissociated by using mild plasma having a low electron temperature in the plasma CVD device 100, a deposition speed (film formation rate) of a silicon oxynitride film is easily controlled. Accordingly, film formation may be performed while controlling a film thickness, for example, from a thin film thickness of several nm to a relatively thick film thickness of dozens of nm.

Next, conditions very suitable for the plasma CVD process will be described using experiment data as an example, on which the present invention is based. Here, a SiCl₄ gas, a N₂ gas, an O₂ gas, and an Ar gas were used as process gases in the plasma CVD device 100 to form a silicon oxynitride film having a film thickness of 14 nm on a silicon substrate, under following conditions. After 24 hours, concentrations of Si, O, and N in the silicon oxynitride film were measured by using X-ray photoelectron spectrum (XPS) analysis. A result of the XPS analysis is shown in FIG. 5.

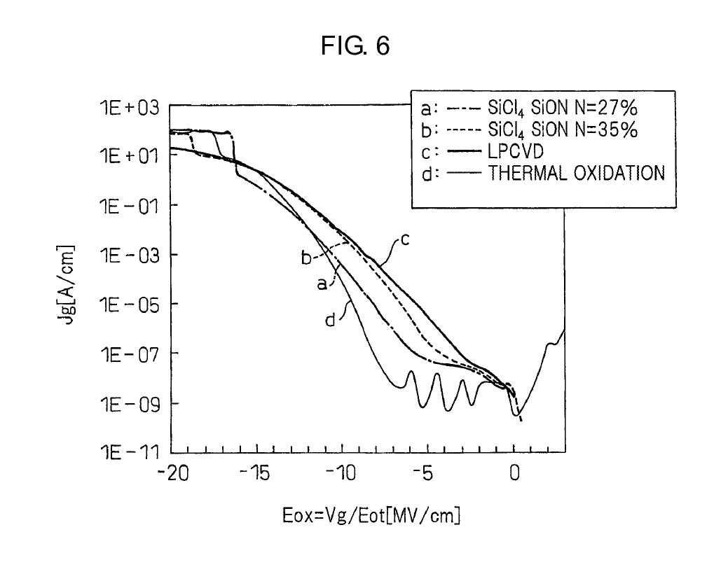

Also, a transistor having a MOS structure was manufactured by forming a polysilicon layer having a film thickness of 150 nm on the formed silicon oxynitride film, and forming a polysilicon electrode by forming a pattern via a photolithography technology. A gate leak current of the transistor having the MOS structure using such a silicon oxynitride film as a gate insulation film was measured according to a common method. Also, for comparison, gate leak currents of transistors using, as gate insulation films of the transistors, silicon dioxide films formed LPCVD and thermal oxidation (WVG: method of generating and supplying vapor by combusting O₂ and H₂ by using a vapor generator) according to following conditions, were also measured. Results of measuring the gate leak currents (I-V curves) are shown in FIG. 6.

(plasma CVD conditions)

process temperature (holding stage): 400° C.

microwave power: 3 kW (power density 1.53 W/cm², per penetration plate area)

process pressure: 2.7 Pa

SiCl₄ flow rate: 1 mL/min (sccm)

N₂ gas flow rate: 450 mL/min (sccm)

O₂ gas flow rate: varied in the order of 0 (not added), 1 mL/min (sccm), 2 mL/min (sccm), 3 mL/min (sccm), 4 mL/min (sccm), 5 mL/min (sccm), and 6 mL/min (sccm)

Ar gas flow rate: 40 mL/min (sccm)

(LPCVD conditions)

process temperature: 780° C.

process pressure: 133 Pa

SiH₂Cl₂ gas+NH₃ gas: 100+1000 mL/min (sccm)

(thermal oxidation condition: WVG)

process temperature: 950° C.

process pressure: 40 kPa

vapor

$$\frac{{O}_{2}}{{H}_{2}} flow rate = \frac{900}{450} mL \text{/} min ( sccm )$$

FIG. 5 shows a result of measuring the concentration of each of Si atoms, O atoms, and N atoms in a SiON film by using XPS analysis, in correlation with an O₂ flow rate during plasma CVD in the horizontal axis. From FIG. 5, it is clear that the N concentration decreases in inverse proportion to increase of the O₂ flow rate during plasma CVD.

Also, concentration of hydrogen atoms in an obtained SiON film was below or equal to 9.9×10²⁰ atoms/cm³ as measured by using secondary ion mass spectrometry (RBS-SIMS). Also, no peak of N—H bonds was detected from the SiON film by using Fourier transform infrared spectroscopy (FT-IR), and thus it was determined that an amount of N—H bonds in the SiON film was below or equal to the lowest limit of detection.

Also, from FIG. 6, it was shown that a silicon oxynitride film formed by using the method of the present invention exhibits a higher gate leak current as compared to a SiO₂ film formed by using LPCVD or thermal oxidation in a low electric field, but is harder to be broken down as compared to a SiO₂ film formed by using LPCVD or thermal oxidation in a high electric field, thus exhibiting a lower gate leak current. According to such results, it was determined that the silicon oxynitride film formed by the method of the present invention is better than a SiO₂ film formed by using LPCVD method or thermal oxidation method in terms of insulating properties and durability.

Also, from FIG. 6, it was determined that a gate leak current of the silicon oxynitride film (curves (a) through (c) of FIG. 6) formed by using the method of the present invention is reduced as the nitrogen concentration in the silicon oxynitride film is decreased. Accordingly, in order to improve electric characteristics (suppression of the gate leak current) of a silicon oxynitride film, in plasma CVD, it was determined that a flow rate of the oxygen containing gas to the flow rate of the all gases (for example, a percentage of flow rate of O₂ gas/flow rate of all gases) may be from 0.1% to 10%, and preferably from 0.2% to 5%.

As described above, in the method for forming a silicon oxynitride film of the present invention, a high quality silicon oxynitride film having excellent insulation property and containing a very small amount of H atoms therein may be fabricated on the wafer W by performing plasma CVD by using a film formation gas including a SiCl₄ gas, a nitrogen gas (N₂), an O₂ gas, and an Ar gas and by selecting a ratio of a flow rates of SiCl₄ gas, nitrogen gas (N₂), O₂ gas or the like, and process pressure. A silicon oxynitride film formed as described above may be advantageously used as a gate insulation film of, for example, a MOS-type semiconductor memory device.

The method of the present invention may be applied to form a silicon oxynitride film constituting, for example, a gate insulation film of a MOS-type semiconductor memory device. Accordingly, the MOS type semiconductor memory device having excellent electric characteristics may be manufactured since a gate leak current is low.

### (Example Applied to Manufacturing of Semiconductor Memory Device)

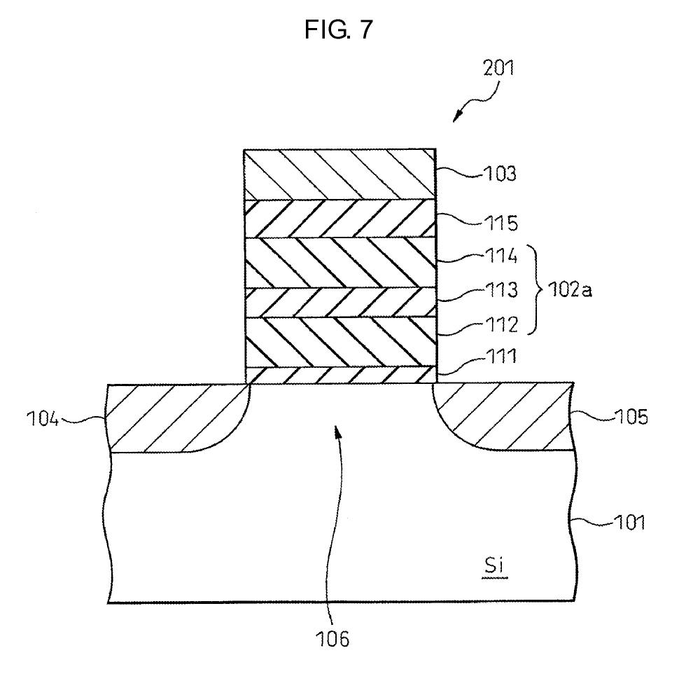

Next, an example of applying the process for production of a silicon oxynitride film according to the present embodiment to a process of manufacturing a semiconductor memory device will be described with reference to FIG. 7. FIG. 7 is a cross-sectional view of a schematic structure of a MOS-type semiconductor memory device 201. The MOS-type semiconductor memory device 201 includes a p-type silicon substrate 101 constituting a semiconductor layer, a plurality of insulation films stacked on the p-type silicon substrate 101, and a gate electrode 103 additionally formed thereon. A first insulation film 111, a second insulation film 112, a third insulation film 113, a fourth insulation film 114, and a fifth insulation film 115 are installed between the silicon substrate 101 and the gate electrode 103. Here, the second, third, and fourth insulation films 112, 113, and 114 are all silicon nitride films, and form a silicon nitride film stacked structure 102a.

Also, in the silicon substrate 101, first source and drain 104 and second source and drain 105 constituting n-type diffusion layers are formed to be disposed on each side of the gate electrode 103 at a predetermined depth from a surface of the silicon substrate 101, and a channel forming region 106 is formed therebetween. Also, the MOS-type semiconductor memory device 201 may be formed on a p-well or a p-type silicon layer formed inside a semiconductor substrate. Also, the present embodiment is explained using a n-channel MOS device as an example, but a p-channel MOS device may be used. Accordingly, descriptions of the present embodiment hereinafter may be applied both to a n-channel MOS device and a p-channel MOS device.

The first insulation film 111, which is a gate insulation film (tunnel insulation film), is a silicon oxynitride film (SiON film) having a very small concentration of hydrogen atoms below or equal to 9.9×10²⁰ atoms/cm³ in a film formed on the surface of the silicon substrate 101 by using the plasma CVD device 100. A film thickness of the first insulation film 111 may be, for example, in the range from 2 nm to 10 nm, and preferably in the range from 4 nm to 7 nm.

The second insulation film 112 forming the silicon nitride film stacked structure 102a is a silicon nitride film (SiN film; here, a composition ratio of Si and N is not definitely determined stoichiometrically, but has different values according to film formation conditions. The same is applied hereinafter) formed on the first insulation film 111. A film thickness of the second insulation film 112 may be, for example, in the range from 2 nm to 20 nm, and preferably in the range from 3 nm to 5 nm.

The third insulation film 113 is a silicon nitride film (SiN film) formed on the second insulation film 112. A film thickness of the third insulation film 113 may be, for example, in the range from 2 nm to 30 nm, and preferably in the range from 4 nm to 10 nm.

The fourth insulation film 114 is a silicon nitride film (SiN film) formed on the third insulation film 113. The fourth insulation film 114 may, for example, have the same film thickness as the second insulation film 112.

The fifth insulation film 115 is a silicon dioxide film (SiO₂ film) deposited on the fourth insulation film 114, for example, via a CVD method. The fifth insulation film 115 operates as a block layer (barrier layer) between the gate electrode 103 and the fourth insulation film 114. A film thickness of the fifth insulation film 115 may be, for example, in the range from 2 nm to 30 nm, and preferably in the range from 5 nm to 8 nm.

The gate electrode 103 is, for example, composed of a polycrystalline silicon film formed by a CVD method, and operates as a control gate (CG) electrode. Alternatively, the gate electrode 103 may be a film including a metal such as W, Ti, Ta, Cu, Al, Au, Pt, or the like. The gate electrode 103 is not limited to a single layer, and may have a stacked structure including, for example, tungsten, molybdenum, tantalum, titan, platinum, a silicide thereof, a nitride thereof, an alloy thereof, etc., so as to increase an operating speed of the MOS-type semiconductor memory device 201 by reducing a specific resistance of the gate electrode 103. The gate electrode 103 is connected to a wire layer (not shown).

Also, in the MOS-type semiconductor memory device 201, the silicon nitride film stacked structure 102a formed by the second, third, and fourth insulation films 112, 113, and 114 is a charge accumulating region that mainly accumulates charges.

The example of applying the method of the present invention to the manufacturing of the MOS-type semiconductor memory device 201 will be described using main procedures as an example. First, the silicon substrate 101 on which an isolation film (not shown) is formed using a method such as a LOCOS (Local Oxidation of Silicon) method, a STI (Shallow Trench Isolation) method, or the like is prepared, and a SiON film is formed as the first insulation film 111 on a surface of the silicon substrate 101 according to the method of the present invention. In other words, a SiON film having a very low concentration of hydrogen atoms below or equal to 9.9×10²⁰ atoms/cm³ in the SiON film is deposited on the silicon substrate 101 by performing plasma CVD by using SiCl₄, N₂, O₂, and Ar as process gases in the plasma CVD device 100 and setting the pressure and the gas flow rate ratio.

Then, the second, third, and fourth insulation films 112, 113, and 114 are sequentially formed on the first insulation film 111, for example, by using a plasma CVD method.

Next, the fifth insulation film 115 is formed on the fourth insulation film 114. The fifth insulation film 115 may be formed, for example, by using a CVD method. Also, a metal film constituting the gate electrode 103 is formed on the fifth insulation film 115, by forming a polysilicon layer, a metal layer, a metal silicide layer, or the like by using, for example, a CVD method.

Then, the metal film and the fifth through first insulation films 115 through 111 are etched by using a patterned resist as a mask using a photolithography technology, thereby obtaining a gate stacked structure having the patterned gate electrode 103 and the plurality of insulation films. Next, a high concentration of n-type impurities are ion-injected into a silicon surface adjacent to both sides of the gate stacked structure, thereby forming the first source and drain 104 and the second source and drain 105. As such, the MOS-type semiconductor memory device 201 having the structure of FIG. 7 may be manufactured. The MOS-type semiconductor memory device 201 manufactured by using the SiON film containing a very small amount of hydrogen atoms as the first insulation film 111 is very reliable, and thus is stably operable.

Also in FIG. 7, the silicon nitride film stacked structure 102a is formed of three layers, i.e., the second through fourth insulation films 112 through 114, but the method of the present invention may also be applied to cases of manufacturing a MOS-type semiconductor memory device having a silicon nitride film structure in which two or four or more silicon nitride films are stacked.

The embodiments of the present invention have been described above, but the present invention is not limited to the above embodiments, and may vary. For example, the silicon oxynitride film formed by using the method of the present invention may be used, for example, as a gate insulation film of a transistor or the like, aside from a gate insulation film of a MOS-type semiconductor memory device.

1. A process for production of a silicon oxynitride film on an object to be processed by using a plasma CVD method in a plasma CVD device that forms a film by generating plasma by introducing microwaves into a process chamber by using a planar antenna having a plurality of apertures, the process comprising forming a silicon oxynitride film having concentration of hydrogen atoms below or equal to 9.9×10²⁰ atoms/cm³ therein as measured by using secondary ion mass spectrometry (SIMS), by setting a pressure inside the process chamber in a range from 0.1 Pa to 6.7 Pa and performing plasma CVD by using process gases including a gas of a compound composed of silicon atoms and chlorine atoms, a nitrogen gas, and an oxygen gas.

2. The process of claim 1, wherein a flow rate ratio of the oxygen gas to entire process gases is in a range from 0.1% to 10%

3. The process of claim 1, wherein no peak of N—H bonds is detected from the silicon oxynitride film by using Fourier transform infrared spectroscopy (FT-IR).

4. The process of claim 1, wherein the compound composed of silicon atoms and chlorine atoms is tetrachlorosilane (SiCl₄).

5. The process of claim 1, wherein a flow rate ratio of the gas of the compound composed of silicon atoms and chlorine atoms to the entire process gases is in a range from 0.06% to 2%.

6. The process of claim 1, wherein a flow rate ratio of the nitrogen gas to entire process gases is in a range from 32% to 99.8%.

7. A silicon oxynitride film produced by using the process of claim 1.

8. A computer-readable storage medium having recorded thereon a control program to be operated on a computer, wherein the control program enables the computer to control a plasma CVD device that generates plasma by introducing microwaves into a process chamber by using a planar antenna having a plurality of apertures and performs film formation so as to form a silicon oxynitride film having concentration of hydrogen atoms below or equal to 9.9×10²⁰ atoms/cm³ in the silicon oxynitride film as measured by using secondary ion mass spectrometry (SIMS) by setting a pressure inside the process chamber in a range from 0.1 Pa to 6.7 Pa and performing plasma CVD by using process gases including a gas of a compound composed of silicon atoms and chlorine atoms, a nitrogen gas, and an oxygen gas.

9. A plasma CVD device for production of a silicon oxynitride film on an object to be processed by using a plasma CVD method, the plasma CVD device comprising:
a process chamber which accommodates the object to be processed and has an opening on a top of the process chamber;
a dielectric member which closes the opening of the process chamber;
a planar antenna which is installed on the dielectric member and has a plurality of apertures for introducing microwaves into the process chamber;
a gas introduction unit which is connected to a gas supply apparatus for supplying process gases into the process chamber;
an exhauster which depressurizes and exhausts an inside of the process chamber; and
a control unit which controls plasma CVD to be performed to set a pressure inside the process chamber to be in a range from 0.1 Pa to 6.7 Pa and to form the silicon oxynitride film having concentration of hydrogen atoms below or equal to 9.9×10²⁰ atoms/cm³ in the silicon oxynitride film, as measured by using secondary ion mass spectrometry (SIMS) by supplying the process gases including gas of a compound composed of silicon atoms and chlorine atoms, nitrogen gas, and oxygen gas from the gas introduction unit connected to the gas supply apparatus.
